(19) United States
(12) Patent Application Publication
(10) Pub. No.: US 2007/0121405 A1
(43) Pub. Date: May 31, 2007

(54) Semiconductor memory device

(75) Inventor: Hiroki Ueno, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/600,186

(22) Filed: Nov. 16, 2006

(30) Foreign Application Priority Data
Nov. 28, 2005 (JP) 2005-341556

(51) Int. Cl. G11C 7/10; G11C 7/00; G11C 8/00

(52) U.S. Cl. 365/219; 365/221; 365/230.03; 365/189.05

(57) ABSTRACT

There is provided a semiconductor memory device for acceleration in burst mode. The semiconductor memory device has a burst mode for serially reading multiple bits of data in synchronization with both edges of a clock. Multiple memory blocks are geometrically arranged correspondingly to the multiple bits. An address selection circuit selects a memory cell from the memory blocks. Data read from the memory blocks is parallel transmitted to an output circuit. The output circuit first outputs data from a memory block to which data is transmitted fastest among the multiple memory blocks. The output circuit serially outputs data in the fixed order in synchronization with both edges of the clock.

### CROSS-REFERENCE TO RELATED APPLICATION

The present application claims priority from Japanese patent application No. 2005-341556 filed on Nov. 28, 2005, the content of which is hereby incorporated by reference into this application.

### BACKGROUND OF THE INVENTION

The present invention relates to a semiconductor memory device. More specifically, the invention relates to a technology effectively used for static RAM having burst mode.

Japanese Unexamined Patent Publication No. 2005-209333 concerns DDR SRAM. The technology described in this publication relates to data input operations in CC mode. Japanese Unexamined Patent Publication No. 2000-298981 provides an example of DRAM that parallel reads multiple bits and serially outputs them for acceleration.

Patent document 1: Japanese Unexamined Patent Publication No. 2005-209333

Patent document 2: Japanese Unexamined Patent Publication No. 2000-298981

### SUMMARY OF THE INVENTION

A burst mode for DDR SRAM processes two or four pieces of data in a single write or read operation. Out of all the data, the slowest data limits a read operation speed. The inventors paid attention to the fact that a string of data follows a stabilized sequence in buffer memory used to transfer a large amount of data. They invented acceleration of burst operation exceeding the above-mentioned limitation by stabilizing a data input/output sequence in the burst mode and devising the memory cell arrangement.

It is an object of the present invention to provide a semiconductor memory device for accelerating burst mode. These and other objects and new features of the invention will become more apparent upon a reading of the following detailed description and drawing of this specification.

The following describes an overview of representative means of the invention disclosed in this application. There is provided a burst mode for serially reading multiple bits of data in synchronization with both edges of a clock. Multiple memory blocks are geometrically arranged correspondingly to the multiple bits. An address selection circuit selects a memory cell from the memory blocks. Data read from the memory blocks is parallel transmitted to an output circuit. The output circuit first outputs data from a memory block to which data is transmitted fastest among the multiple memory blocks. The output circuit serially outputs data in the fixed order in synchronization with both edges of the clock.

The fastest one of all data determines an operation speed to enable acceleration.

### BRIEF DESCRIPTION OF THE DRAWINGS

FIG. 1 is an overall block diagram showing an embodiment of SRAM according to the invention;

FIG. 2 is an overall block diagram showing another embodiment of SRAM according to the invention;

FIG. 3 is an overall block diagram showing still another embodiment of SRAM according to the invention;

FIG. 4 is an overall block diagram showing yet another embodiment of SRAM according to the invention;

FIG. 5 is an overall block diagram showing still yet another embodiment of SRAM according to the invention;

FIG. 6 is an overall block diagram showing yet still another embodiment of SRAM according to the invention;

FIG. 7 is an overall block diagram showing still yet another embodiment of SRAM according to the invention;

FIG. 8 is an explanatory diagram showing a memory cell selection path, a data output path, and a delay time;

FIG. 9 is a circuit diagram showing an embodiment of circuit A in FIG. 8;

FIG. 10 is an explanatory diagram focusing on the memory cell selection path and the data output path in FIG. 1;

FIGS. 11(A) to 11(C) show configuration diagrams of circuits (a) to (c) in FIG. 10 according to an embodiment;

FIG. 12 is an operation waveform showing an embodiment of DDR SRAM according to the invention; and

FIG. 13 is a conceptual diagram showing an application of the semiconductor memory device according to the invention.

### DETAILED DESCRIPTION OF THE PREFERRED EMBODIMENTS

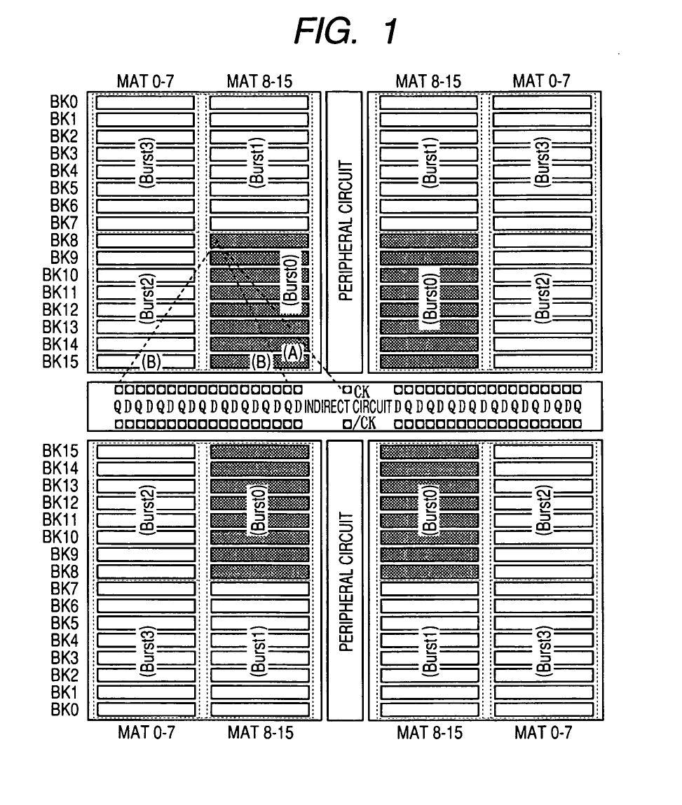

FIG. 1 provides an overall block diagram showing an embodiment of SRAM according to the invention. In FIG. 1, the arrangement of blocks corresponds to the geometric arrangement on an actual semiconductor chip. In FIG. 1, a semiconductor chip is vertically long. The semiconductor chip is divided into four areas by a vertical center portion and a horizontal center portion. A memory cell array is formed in each of four areas.

The four memory cell arrays are arranged left-right symmetrically against the vertical center portion and are arranged up-down symmetrically against the horizontal center portion. One memory cell array is vertically divided into 16 blocks BK0 through BK15 and is horizontally divided into 16 mats MAT0 through MAT15. The blocks BK0 through BK15 are selected X-coordinate addresses. The mats MAT0 through MAT15 are selected X-coordinate addresses. For example, block BK0 and mat MAT0 select one memory mat composed of 256 word lines and 9×32 pairs of complementary bit lines. Therefore, there are arranged 256×32×9=73728 memory cells. The memory cell belongs to a static memory cell.

As mentioned above, one memory cell array is provided with 256 (16×16) memory mats specified by 16 blocks (BK0 through BK15) and 16 mats (MAT0 through MAT15). The 256 memory mats are grouped into four sets when four bits are read or written in the burst mode, for example. In this case, the one memory cell array is vertically and horizontally grouped into four memory blocks (Burst0), (Burst1), (Burst2), and (Burst3) each composed of 8×8=64 memory mats. The four memory blocks (Burst0) through (Burst3) correspond to an output sequence (Burst0)→(Burst1)→(Burst2)→(Burst3) in the burst mode.

Memory block (Burst0) corresponds to the firstly output data. Data needs to be transmitted to memory block (Burst0) fastest of the four memory blocks (Burst0) through (Burst3). Memory block (Burst0) is selected so as to be shortest from output terminal Q and clock input terminal CK provided at the chip center. In FIG. 1, straight path (A) indicated by the broken line corresponds to a selection path synchronized with clock CK. Straight path (B) indicated by the broken line corresponds to a 9-bit data output path. The smallest sum of straight paths (A) and (B) determines memory block (Burst0) corresponding to the firstly output data. Such memory block contains 64 memory mats that are shaded near the chip center and are specified by blocks BK8 through BK15 and mats MAT8 through MAT15. The memory mat specified by straight paths (A) and (B) corresponds to memory block (Burst0) where data is output latest. A delay time for this path determines the operation speed in the burst mode and can contribute to acceleration of the burst mode.

Adjacently, blocks BK0 through BK7 and mats MAT8 through MAT15 specify 64 memory mats along the vertical chip center. These memory mats are defined to be memory block (Burst1) corresponding to the secondly output data. Blocks BK8 through BK15 and mats MAT0 through MAT8 specify 64 memory mats along the horizontal chip center. These memory mats are defined to be memory block (Burst2) corresponding to the thirdly output data. Blocks BK0 through BK8 and mats MAT0 through MAT8 specify 64 memory mats at the chip corner. These memory mats are defined to be memory block (Burst3) corresponding to the finally output data.

Each one of the above-mentioned memory mats has nine sense amplifiers to perform read and write operations in units of nine bits. For example, the nine bits include one-byte data and one parity bit. An indirect circuit in the horizontal center portion includes nine data output terminals Q and nine data input terminals D adjacently to the memory cell array. The data output terminals Q and the data input terminals D are alternately arranged in pairs correspondingly to the 9-bit data. An input circuit and an output circuit are arranged correspondingly to the data output terminals Q and the data input terminals D. The entire semiconductor chip is provided with the four memory cell arrays. A region adjacent to each memory cell array includes nine data output terminals Q and nine data input terminals D. Accordingly, there are provided 9×4=36 terminals in total. A noninverting clock CK and an inverting clock /CK are provided at the chip center.

One memory cell array allows selection of one memory mat at a time in the four memory blocks (Burst0) through (Burst3). Each memory mat parallel supplies 9×4 bits of data to an output circuit corresponding to the output terminal Q via a signal line vertically arranged in the diagram. The similar selection is also performed for the remaining three memory cell arrays. Each memory mat parallel supplies 9×4 bits of data to an output circuit corresponding to the output terminal Q via the vertically arranged signal line. The entire chip serially outputs 36×4 bits of data four times in units of 36 bits from the data output terminals Q.

In terms of the entire memory chip, the input circuit is serially supplied with 36 bits of data four times correspondingly to the 36 data input terminals D. Each input circuit corresponding to the memory cell array converts the data into 9×4 bits of parallel data. A write amplifier simultaneously writes the converted data to one of memory mats corresponding to the four memory blocks (Burst0) through (Burst3).

The indirect circuit at the chip's horizontal center portion is provided with the output circuit, the input circuit, and the clock input circuit as mentioned above. In addition, though omitted from the drawing, the indirect circuit is also provided with an address terminal and a control terminal as well as input circuits for them. The chip's vertical center portion is mainly provided with address selection circuits as peripheral circuits. For example, the address selection circuits include a word line selection circuit, a bit line selection circuit, and a sense/write amplifier selection circuit. The selection circuit is also provided with logic circuits such as a decoder and a pre-decoder, and a relay buffer for transmitting a timing signal. A sub-word driver is provided between memory mats. That is, the word line is configured to be a hierarchical word line composed of a main word line and a sub-word line. The sub-word driver selects a sub-word line. The memory cell is connected to the sub-word line. The use of such hierarchical word line architecture accelerates selection of the word line connected to the memory cell to be selected and decreases the electric current consumption for a non-selected memory cell.

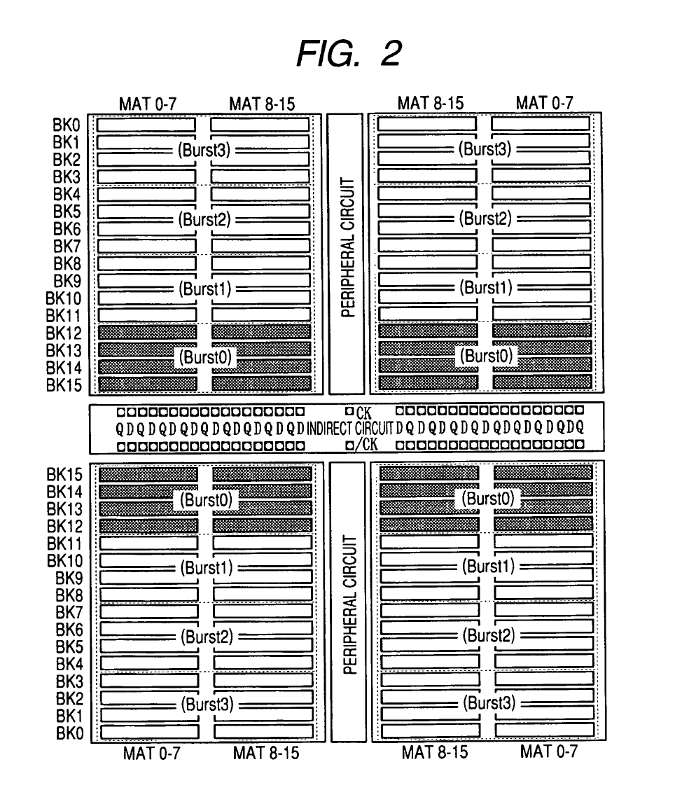

FIG. 2 provides an overall block diagram showing another embodiment of SRAM according to the invention. This embodiment is a modification of the embodiment in FIG. 1. Memory block (Burst0) stores firstly read data and corresponds to 64 memory mats specified by blocks BK12 through BK15 and mats MAT0 through MAT15 (shaded) adjacent to the chip center. Memory block (Burst1) stores secondly read data and corresponds to 64 memory mats specified by blocks BK8 through BK11 and mats MAT0 through MAT15. Memory block (Burst2) stores thirdly read data and corresponds to 64 memory mats specified by blocks BK4 through BK7 and mats MAT0 through MAT15. Memory block (Burst3) stores lastly read data and corresponds to 64 memory mats specified by blocks BK0 through BK3 and mats MAT0 through MAT15.

In FIG. 2, the top left memory mat in the memory block (Burst0) requires the longest reading time from the beginning of the memory cell selection to the output circuit. A delay time occurs on the selection path and the data output path for the memory cell corresponding to that memory mat. The delay time for these paths determines the operation speed in the burst mode and can contribute to acceleration of the burst mode. Compared to FIG. 1, the construction in FIG. 2 shortens a Y-direction distance and elongates an X-direction distance with reference to clock CK. The construction in FIG. 2 also shortens a Y-direction distance and elongates an X-direction distance for the data output path to the right-end terminal Q.

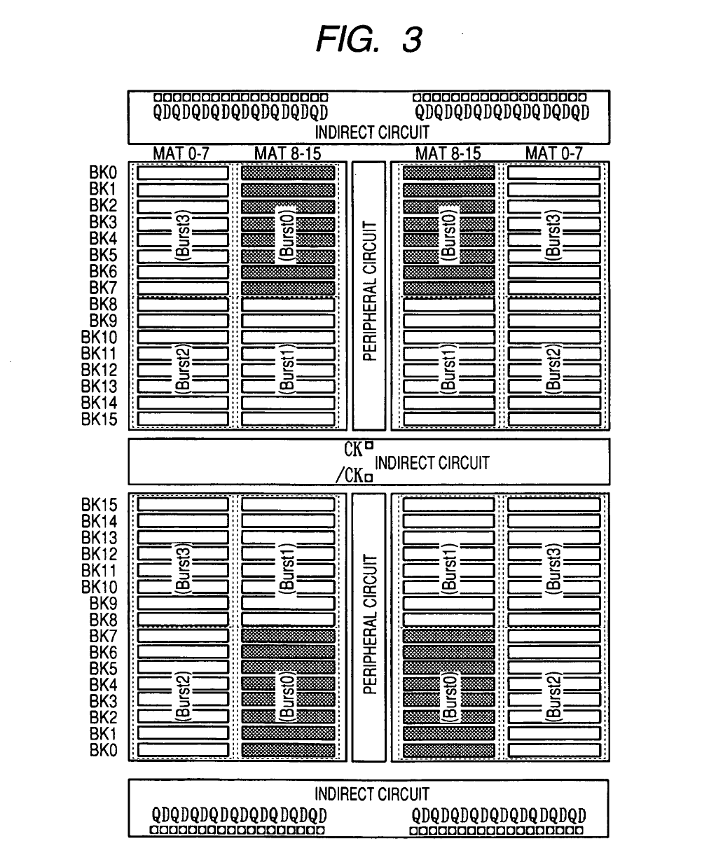

FIG. 3 provides an overall block diagram showing still another embodiment of SRAM according to the invention. The embodiment provides an indirect circuit for top and bottom ends of the chip. That is, a region adjacent to the memory cell array includes nine data output terminals Q and nine data input terminals D. The data output terminals Q and the data input terminals D are alternately arranged in pairs correspondingly to the above-mentioned 9-bit data. An output circuit and an input circuit are provided corresponding to the data output terminals Q and the data input terminals D.

Memory block (Burst0) stores firstly read data and corresponds to 64 memory mats specified by blocks BK0 through BK7 and mats MAT8 through MAT15 (shaded in FIG. 3) adjacent to the top and bottom centers. Memory block (Burst1) stores secondly read data and corresponds to 64 memory mats specified by blocks BK8 through BK15 and mats MAT8 through MAT15 adjacent to the chip center. Memory block (Burst2) stores thirdly read data and corresponds to 64 memory mats specified by blocks BK0 through BK7 and mats MAT0 through MAT7 to the outside of the chip's top and bottom. Memory block (Burst3) stores lastly read data and corresponds to 64 memory mats specified by blocks BK8 through BK15 and mats MAT0 through MAT7 outside the chip center.

In FIG. 3, data is latest output to the bottom right and top left memory mats in the memory block (Burst0). That is, the data output path corresponds to the bottom right of the memory block. The memory cell selection path as a clock transmission path corresponds to the top left of the memory block. An operation speed in the burst mode is determined by a delay time corresponding to the data output path or the memory cell selection path whichever is later. This makes it possible to accelerate the burst mode.

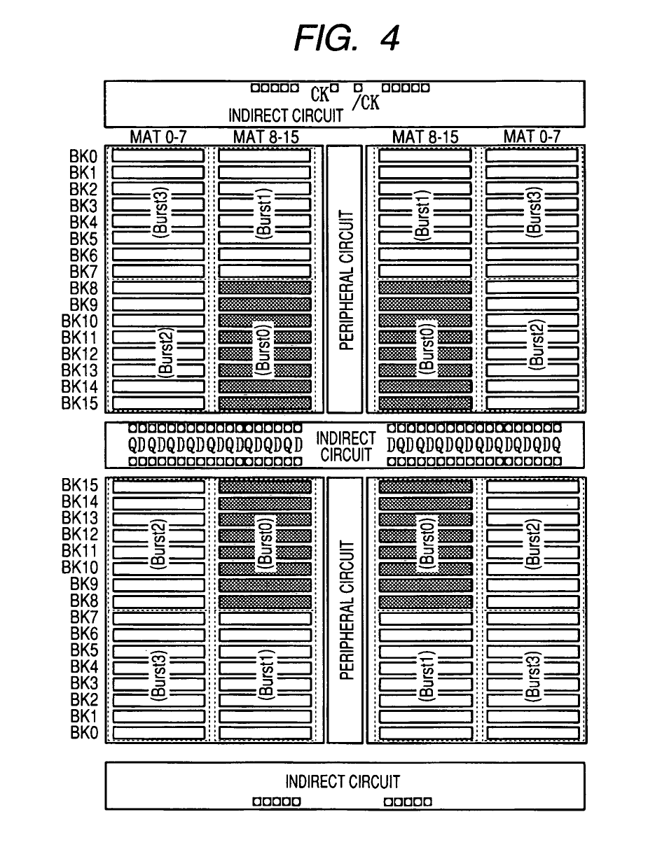

FIG. 4 provides an overall block diagram showing yet another embodiment of SRAM according to the invention. The embodiment provides the top and bottom of the chip with indirect circuits corresponding to the clocks CK and /CK, and the address terminal and the control terminal separately from the indirect circuit in FIG. 1. The top is provided with the clocks CK and /CK. The bottom is provided with approximately half of the address and control terminals. The embodiment employs the same arrangement of four memory blocks (Burst0) through (Burst3) as that of the embodiment in FIG. 1. The embodiment focuses on data terminal Q to determine the arrangement of four memory blocks (Burst0) through (Burst3) as mentioned above. When the clock CK causes a delay time along the selection path for the memory cell, the delay may be longer than a delay time along the data path. In such case, it only needs to replace (Burst0) and (Burst1) with each other. Similarly, (Burst2) and (Burst3) may be replaced with each other.

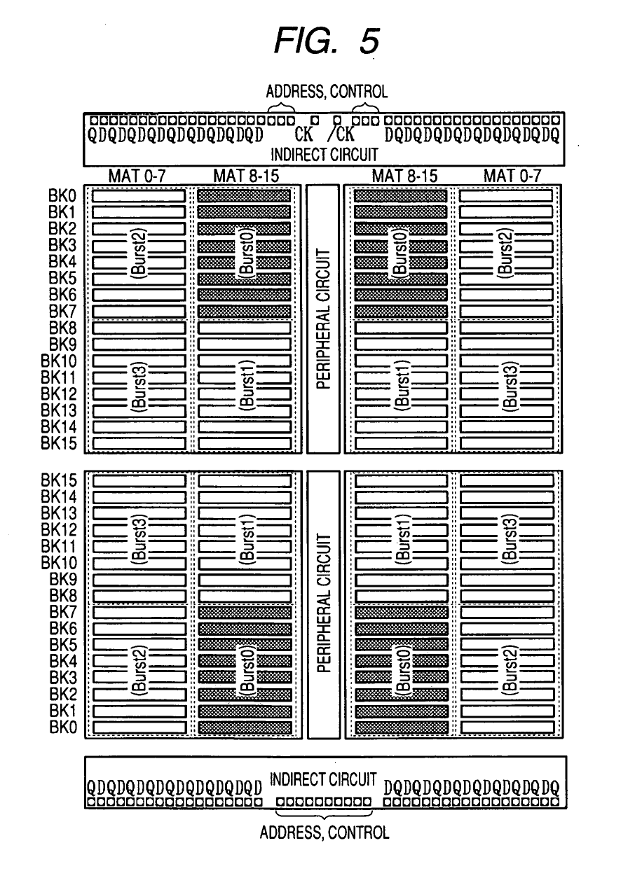

FIG. 5 provides an overall block diagram showing still yet another embodiment of SRAM according to the invention. The embodiment distributes the indirect circuit at the center in FIG. 4 to the top and bottom of the chip. The indirect circuit in FIG. 4 includes data output terminals Q, data input terminals D, the output circuit, and the input circuit. In FIG. 5, the top is provided with only the clocks CK and /CK. The bottom is provided with approximately half of the address and control terminals. The embodiment uses the same arrangement of four memory blocks (Burst0) through (Burst3) as that for the embodiment in FIG. 3.

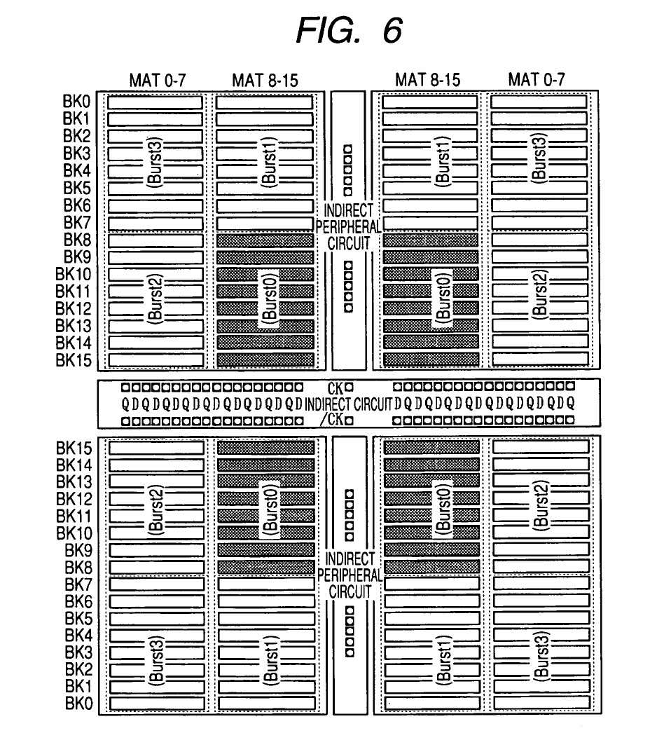

FIG. 6 provides an overall block diagram showing yet still another embodiment of SRAM according to the invention. The embodiment provides the indirect circuit for address and control terminals to the vertical center portion for the peripheral circuit in FIG. 1. Therefore, the vertical center portion functions as an indirect peripheral circuit. The remainder of the construction is the same as that in FIG. 1.

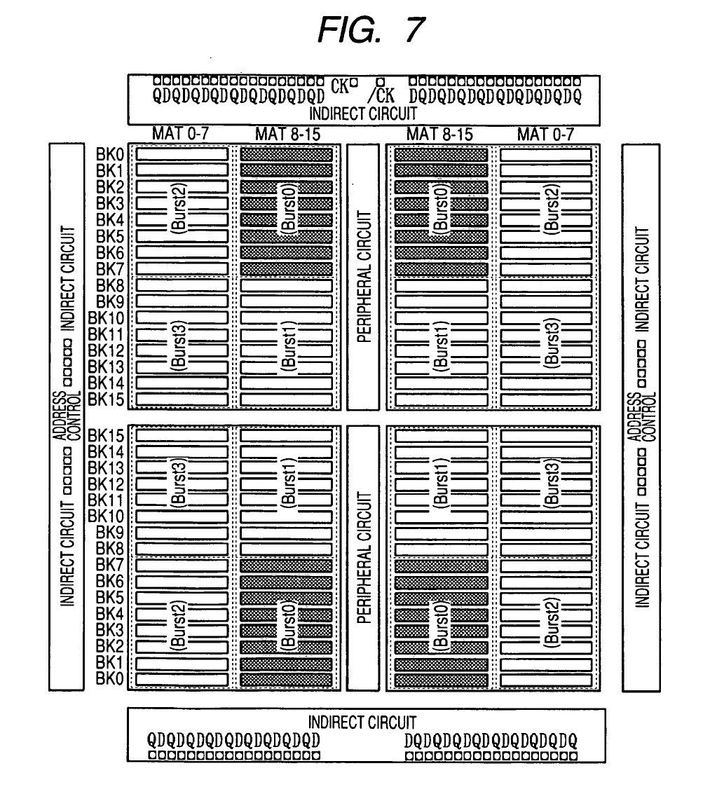

FIG. 7 provides an overall block diagram showing still yet another embodiment of SRAM according to the invention. The embodiment distributes the indirect circuits for address and control terminals at the top and bottom ends in FIG. 5 to the right and left ends of the chip. The embodiment uses the same arrangement of four memory blocks (Burst0) through (Burst3) as that for the embodiment in FIG. 5. The embodiment arranges all pads corresponding to external terminals along the periphery of the memory chip. When a package is assembled, wire bonding can be used to connect the pads with lead terminals.

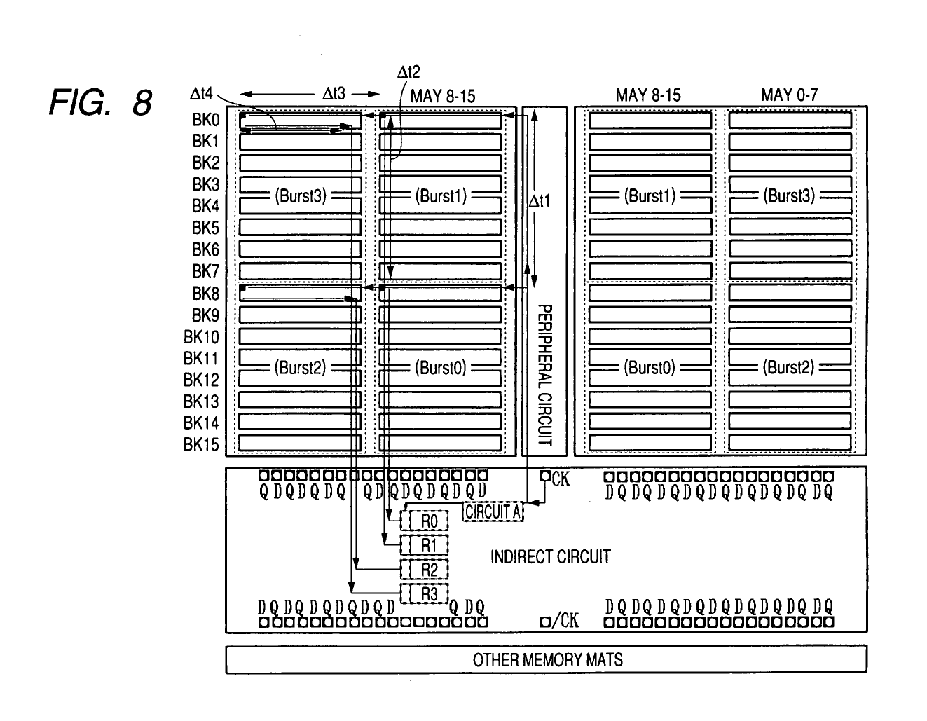

FIG. 8 is an explanatory diagram showing the memory cell selection path, the data output path, and the delay time in FIG. 1. FIG. 8 exemplifies a top half of the memory chip. The left part of the two memory cell arrays is used as an example to illustrate signal transmission paths and corresponding delay times. An address signal is input based on a clock supplied from the clock CK. The peripheral circuit is provided with the address selection circuit such as a decoder. The address selection circuit parallel selects nine memory cells from each of the four memory blocks (Burst0) through (Burst3). The signal transmission path for reading from memory cells is provided for the vertical center portion of the memory cell array, i.e., between the memory blocks (Burst0) (Burst1) and (Burst2) (Burst3) In FIG. 8, a thin line indicates a path that selects a memory cell causing the longest delay time out of the memory blocks (Burst0) through (Burst3) to output data. A clock is propagated along the peripheral circuit (shown horizontally in FIG. 8 and vertically in FIG. 1). In synchronization with the clock, the peripheral circuit transmits not only a block selection signal, a mat selection signal, and a word line selection signal, but also a sense amplifier selection signal and a bit line selection signal (to be described) to each memory mat. These selection signals are transmitted in the direction (downward in FIG. 8 or leftward in FIG. 1) orthogonal to the peripheral circuit arranged at the vertical center of the chip in FIG. 8.

Data from the selected memory cell is transmitted to output terminal D of the indirect circuit arranged at the right in FIG. 8 (at the bottom in FIG. 1). There are provided four registers as the indirect circuit. The four registers R0 through R3 are supplied with clock CK via circuit A to incorporate the transmitted data. To implement a fast burst operation, the embodiment does not incorporate data into the four registers R0 through R3 at the same timing. Instead, circuit A generates a clock signal so as to provide a time difference corresponding to a timing of data transmitted to the registers R0 through R3. With reference to register R0, registers R1, R2, and R3 incorporate data in accordance with successively delayed clocks.

With reference to memory block (Burst0), memory blocks (Burst1) (Burst3) are subject to a delay time increased by Δt1 in the direction along the peripheral circuit. Memory block (Burst3) is subject to a delay time increased by Δt3 in the direction orthogonal to the peripheral circuit. Memory blocks (Burst1) (Burst3) are subject to a delay time increased by Δt2 along the path for reading data from the memory cell. Memory blocks (Burst2) (Burst3) are subject to a delay time increased by Δt4, i.e., a delay time for transferring a read signal from the left-end memory cell to the vertical center portion for the memory cell array.

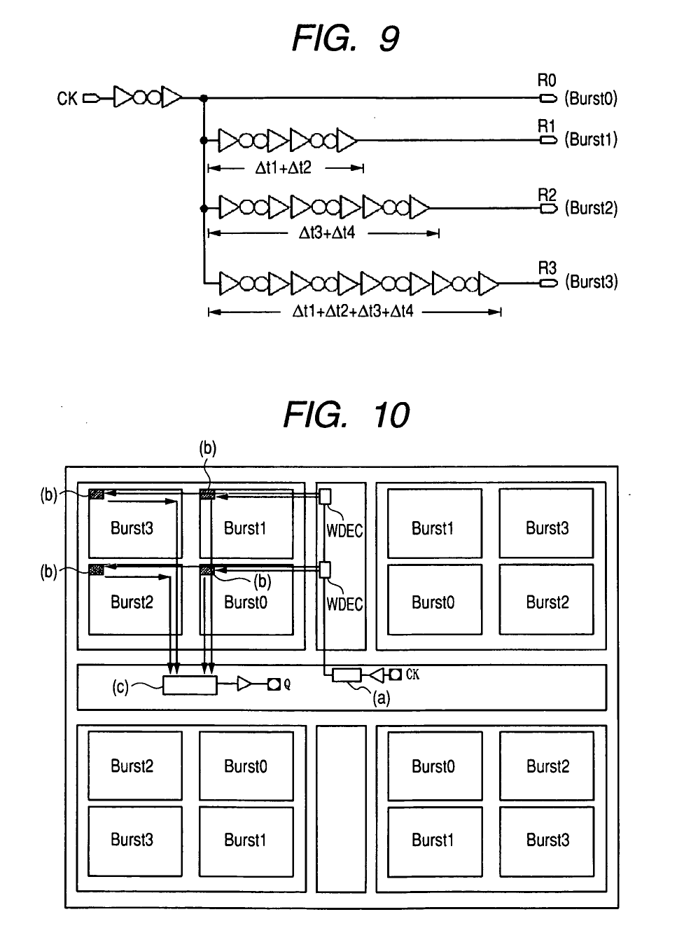

FIG. 9 provides a circuit diagram showing an embodiment of circuit A in FIG. 8. Clock CK passes through a driver composed of an inverter circuit and is transmitted to register R0 corresponding to memory block (Burst0). Based on this, a clock transmitted to register R1 corresponding to memory block (Burst1) passes through a delay circuit equivalent to the delay time Δt1+Δt2. Similarly, a clock transmitted to register R2 corresponding to memory block (Burst2) passes through a delay circuit equivalent to the delay time Δt3+Δt4. A clock transmitted to register R3 corresponding to memory block (Burst3) passes through a delay circuit equivalent to the delay time Δt1+Δt2+Δt3+Δt4.

A conventional burst mode incorporates the latest transmitted data with the delay time Δt1+Δt2+Δt3+Δt4 and then performs parallel/serial conversion. By contrast, the embodiment can output data incorporated into register R0 the instant that the data is incorporated into register R0. Accordingly, the embodiment can accelerate a burst operation.

FIG. 10 provides an explanatory diagram focusing on the memory cell selection path and the data output path in FIG. 1. FIG. 10 outlines the entire memory chip. A circuit (a) represents an address input portion. A circuit (b) represents a memory mat portion. A circuit (c) represents an output portion. In terms of the indirect circuit, the circuit (a) is used commonly to the four memory cell arrays. The circuit (c) is provided correspondingly to the individual memory cell arrays. FIG. 10 exemplifies one circuit for one memory cell array.

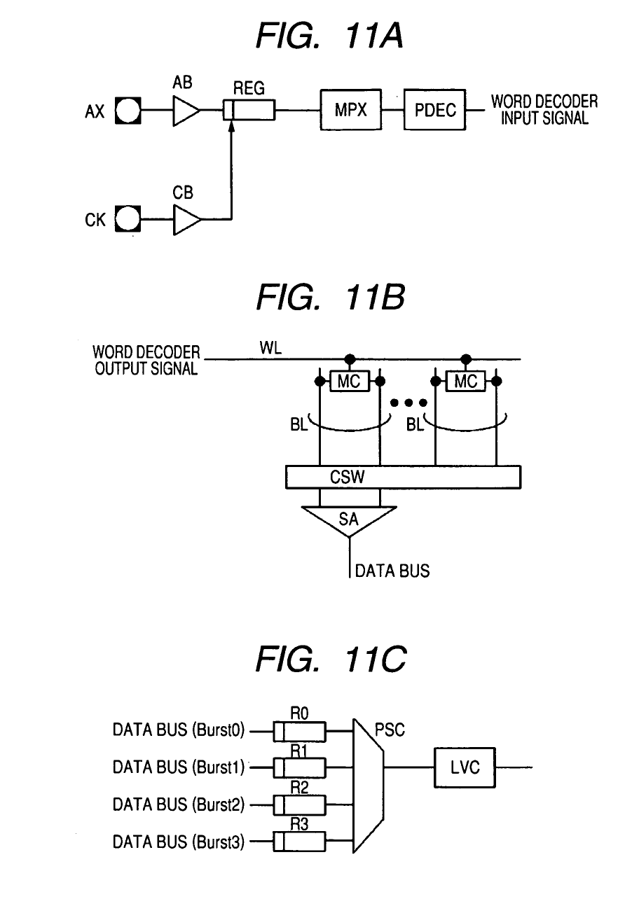

FIGS. 11(A) to 11(C) show configuration diagrams of the circuits (a) through (c) in FIG. 10 according to an embodiment. FIG. 11(A) shows an address input portion of the circuit (a). Address signal AX passes through address buffer AB and is transmitted to register REG (latch circuit). The register REG incorporates the transmitted address signal synchronously with the clock supplied from clock terminal CK and clock buffer CB. An output signal from register REG passes through multiplexer MPX and is transmitted to pre-decoder PDEC. Multiplexer MPX is provided for transmitting the incorporated address signal to a write decoder during a write operation. An output signal from pre-decoder PDEC is transmitted to word decoder WDEC in FIG. 10 to form a selection signal for the word line.

FIG. 11(B) shows a memory mat portion of the circuit (b) A selection terminal of the memory cell is connected to word line WL. An input/output terminal thereof is connected to complementary bit line BL. The memory cell represents a known static memory cell. For example, the memory cell includes a CMOS latch circuit and an address selection MOSFET. The CMOS latch circuit cross-connects input and output terminals of the CMOS inverter circuit. The MOSFET is provided between the pair of input and output terminals and the complementary bit line. A column switch CSW selects one of the 32 pairs of complementary bit lines. The selected pair is connected to an input terminal of a sense amplifier SA. One memory mat is provided with nine pairs of complementary bit lines BL, column switches CSW, and sense amplifiers SA according to the same construction as mentioned above. As a whole, the memory mat reads data in units of nine bits.

FIG. 11(C) shows an output portion of the circuit (c). Data is incorporated into registers R0, R1, R2, and R3 corresponding to the memory blocks (Burst0) through (Burst3). A parallel/serial conversion circuit PSC converts the incorporated data into serial data. A level conversion circuit LVC converts the serial data level. The data is output via an output buffer. Though not limited, the SRAM according to the embodiment allows the peripheral circuit for address and data to operate on 1.5 V and the internal circuit such as the address selection circuit for memory cells to operate on 1 V. The level conversion circuit LVC converts the 1 V amplification data into 1.5 V amplification data.

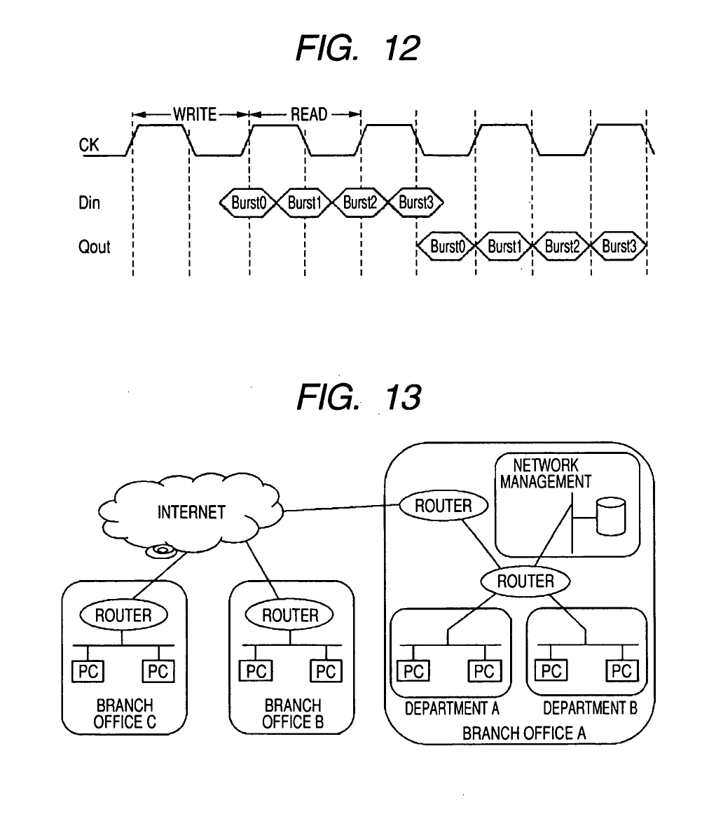

FIG. 12 provides an operation waveform showing an embodiment of the DDR SRAM according to the invention. An address signal and a control signal are input to specify the write mode. The DDR SRAM incorporates input data Burst0-Burst1-Burst2-Burst3 corresponding to the memory blocks (Burst0) through (Burst3) in synchronization with rising and falling timings of clock CK with a one-clock delay. The input data Burst0-Burst1-Burst2-Burst3 is supplied so as to precede the respective timings and ensure the setup time.

An address signal and a control signal are input to specify the read mode. The DDR SRAM supplies output data Burst0-Burst1-Burst2-Burst3 corresponding to the memory blocks (Burst0) through (Burst3) in synchronization with rising and falling timings of clock CK with a delay of one and a half clocks. The read mode can be specified during an input operation in the write mode. The read and write operations allow the latch circuit to hold the address signal. The serial input and output operations are simultaneously available because input terminal D and output terminal Q are provided independently. After the above-mentioned data is input, the write operation is performed at a time. During the write operation, the necessary data is parallel read and is held in registers R0 through R3. Data is simultaneously input and output so as not to compete for selection of the memory cells.

FIG. 13 provides a conceptual diagram showing an application of the semiconductor memory device according to the invention. PC represents a personal computer. In branch office A, each of departments A and B is provided with PCs that are interconnected via LAN. A router is used to interconnect LANs between the departments in branch office A. The Internet interconnects branch offices A through C via the routers. The DDR SRAM according to the embodiment is mounted on the router and is used as relay memory for transferring data between the PCs. Since a bunch of data is transferred, a serial data string is fixed in the relaying memory. No problem is expected even though the order of serial input or output is fixed in the burst operation as mentioned above.

While there have been described specific preferred embodiments of the present invention, it is to be distinctly understood that the present invention is not limited thereto but may be otherwise variously embodied within the spirit and scope of the invention. For example, various embodiments are available for the construction of the memory mat, the memory block, and the memory cell array. The invention can be widely used for a semiconductor memory device having burst mode.

What is claimed is:

1. A semiconductor memory device having burst mode for serially reading a plurality of bits of data in a fixed order in synchronization with both edges of a clock, the device comprising:
a plurality of geometrically arranged memory block correspondingly to the plurality of bits;
an address selection circuit for selecting a memory cell in the plurality of memory blocks; and
an output circuit for parallel transmitting read data resulting from selecting a memory cell from the plurality of memory blocks and serially outputting data in the fixed order in synchronization with both edges of a clock,
wherein the output circuit first outputs data from a memory block to which data is transmitted fastest among the plurality of memory blocks.

2. The semiconductor memory device according to claim 1,
wherein the plurality of output circuits are provided.

3. The semiconductor memory device according to claim 2,
wherein a memory cell address is geometrically allocated according to X and Y directions in the plurality of memory blocks; and
wherein the output circuit first outputs data from a memory block nearest to the clock input circuit and the output circuit.

4. The semiconductor memory device according to claim 3, further comprising:
a write circuit that converts serially input write data into parallel data correspondingly to the fixed order and simultaneously writes data to the plurality of memory blocks,
wherein an input terminal for the write data is arranged adjacently to an output terminal of the output data.

5. The semiconductor memory device according to claim 4,
wherein the memory cell represents a static memory cell.

6. The semiconductor memory device according to claim 5,
wherein the output circuit includes a plurality of latch circuits that hold data parallel transmitted from the plurality of memory blocks in accordance with a clock, and
wherein the clock input circuit transmits a delayed clock to the latch circuit in consideration for data transmitted from the plurality of memory blocks.

7. The semiconductor memory device according to claim 5,
wherein there are provided the four memory blocks,
wherein the four memory blocks are each allocated to four areas formed by dividing a rectangular semiconductor chip by a vertical center portion and a horizontal center portion,
wherein the input and output terminals are arranged at a boundary of the horizontal center portion adjacent to each of the memory blocks, and
wherein the vertical center portion is provided with a peripheral circuit including the address selection circuit.

8. The semiconductor memory device according to claim 5,
wherein there are provided the four memory blocks,
wherein the four memory blocks are each allocated to four areas formed by dividing a rectangular semiconductor chip by a vertical center portion and a horizontal center portion,
wherein both sides along a vertical direction are provided with an indirect circuit where the input and output terminals are arranged, and
wherein the vertical center portion is provided with a peripheral circuit including the address selection circuit.

9. The semiconductor memory device according to claim 5,
wherein there are provided the four memory blocks,
wherein the four memory blocks are each allocated to four areas formed by dividing a rectangular semiconductor chip by a vertical center portion and a horizontal center portion,
wherein both sides along the vertical direction are provided with an indirect circuit where the input and output terminals are arranged,
wherein the vertical center portion is provided with a peripheral circuit including the address selection circuit, and
wherein both sides along a horizontal direction are provided with an indirect circuit where an address terminal and a control terminal are arranged.
